(19) United States
(12) Patent Application Publication
(10) Pub. No.: US 2006/0261431 A1
(43) Pub. Date: Nov. 23, 2006

(54) Pixels for CMOS image sensors

(75) Inventors: Yi-Tae Kim, Suwon-si (KR); Young-Chan Kim, Seongnam-si (KR); Hae-Kyung Kong, Suwon-si (KR); Sung-Ho Choi, Seoul (KR)

Correspondence Address: F. CHAU & ASSOCIATES, LLC, 130 WOODBURY ROAD, WOODBURY, NY, 11797, US

(73) Assignee: SAMSUNG ELCTRONICS CO., LTD.

(21) Appl. No.: 11/436,278

(22) Filed: May 18, 2006

(30) Foreign Application Priority Data
May 18, 2005 (KR) 2005-41607

(51) Int. Cl. H01L 31/06

(52) U.S. Cl. 257/462

(57) ABSTRACT

A unit pixel of a complementary metal-oxide semiconductor (CMOS) image sensor includes a photoelectric conversion element, a transfer transistor, a boosting capacitor and a signal transfer circuit, where the photoelectric conversion element generates a charge based on incident light, the transfer transistor transfers the charge to a floating diffusion node in response to a transfer control signal, the boosting capacitor is disposed between a gate of the transfer transistor and the floating diffusion node, the signal transfer circuit transfers an electric potential of the floating diffusion node in response to a selection signal, and a dynamic range of the electric potential of the floating diffusion node may be widened and a drain-source voltage difference of the transfer transistor may be increased so that the charge transfer efficiency may be enhanced.

### CROSS-REFERENCE TO RELATED APPLICATION

This application claims foreign priority under 35 U.S.C. § 119 to Korean Patent Application No. 200541607, filed on May 18, 2005 in the Korean Intellectual Property Office (KIPO), the contents of which are herein incorporated by reference in their entirety.

### BACKGROUND OF THE INVENTION

1. Field of the Invention

The present disclosure relates to image sensors, and more particularly relates to complementary metal-oxide semiconductor (CMOS) image sensors.

2. Description of the Related Art

An image sensor is a semiconductor module that converts a photo image into an electric signal. Image sensors are widely used in digital cameras, cellular phones with built-in cameras, vision systems, and the like.

Two types of image sensors are commonly available on the market. One is a charge-coupled device (CCD) type image sensor and the other is a complementary metal-oxide semiconductor (CMOS) type image sensor. The CMOS type image sensor has worse noise characteristics and image quality compared with the CCD type image sensor. However, the CCD type image sensor has disadvantages in terms of production costs and power consumption, compared with the CCD type image sensor. The CMOS type image sensor can be manufactured by a conventional semiconductor manufacturing process and can be integrated with peripheral systems for signal amplification or signal processing. In addition, the CMOS type image sensor has advantages in terms of processing speed and power consumption compared with the CCD type image sensor. However, the CMOS type image sensor has disadvantages in terms of noise, image quality, a low signal-to-noise ratio (SNR) and a limited dynamic signal range, compared with the CCD type image sensor.

The conventional CMOS image sensors have three types of structures, such as a 1-transistor structure, a 3-transistor structure and a 4-transistor structure. Among the three types of CMOS image sensor structures, the 4-transistor structure is the most widely used. A unit pixel of the 4-transistor structure CMOS image sensor includes one photo diode and four CMOS transistors. Photo-generated charge integrated in the photo diode is controlled and transferred by the four CMOS transistors.

FIG. 1 is a circuit diagram illustrating a conventional unit pixel of a 4-transistor structure CMOS image sensor that is indicated generally by the reference numeral 100. Referring to FIG. 1, the unit pixel 100 of the CMOS image sensor includes a photo diode 110, a transfer transistor 120, a reset transistor 130, a source follower transistor 140 and a selection transistor 150.

The photo diode 110 integrates photo-generated charge on the basis of incident light. The transfer transistor 120 transfers the photo-generated charge integrated in the photo diode 110 to a floating diffusion node FD in response to a transfer control signal TX. The reset transistor 130 resets the floating diffusion node FD so that the floating diffusion node FD has an initial electric potential in response to a reset control signal RX.

The source-follower transistor 140 detects variation of an electric potential of the floating diffusion node FD, and the selection transistor 150 transfers the electric potential detected by the source-follower transistor 140 to an internal circuit (not shown in FIG. 1). For example, the internal circuit may include a sampling circuit, which samples a signal that is detected by the selection transistor 150 and is transferred by the source follower transistor 140, and an amplification circuit, which amplifies a signal sampled by the sampling circuit.

Hereinafter, an operation of the unit pixel of the CMOS image sensor illustrated in FIG. 1 will be described. When the reset transistor 130 is turned on as the reset control signal RX is activated to a high level, the electric potential of the floating diffusion node FD is initialized to a level of a power supply voltage VDD. The source follower transistor 140 and the selection transistor 150 detect the electric potential of the floating diffusion node 140 so that the detected electric potential becomes an initial electric potential of the floating diffusion node FD. The detected electric potential, i.e., the initial electric potential of the floating diffusion node FD, is referred to as a reference electric potential.

During a photo integration period, electron hole pairs (EHP) are generated in the photo diode 110. The number of electron hole pairs generated in the photo diode 110 is proportional to an intensity of light incident on the photo diode 110.

When a channel is established in the transfer transistor 120 as the transfer control signal TX is activated to a high level, a charge integrated in the photo diode 110 is transferred to the floating diffusion node FD. Therefore, the electric potential of the floating diffusion node FD decreases in proportion to the charge transferred by the photo diode 110 and an electric potential of a source of the source-follower transistor 140 varies as a result.

When the selection transistor 150 is turned on, the electric potential of the floating diffusion node FD, which is referred to as a data electric potential, is transferred to the internal circuit. A light sensing operation of the CMOS image sensor may be performed by correlation double sampling (CDS). For example, the light sensing operation is performed by comparing the data electric potential to the initial electric potential of the floating node. After the light sensing operation finishes, the resetting operation of the floating diffusion node FD is repeated and the other operations stated above are repeated.

As explained above, the CMOS image sensor performs the light sensing operation by detecting the variation of the electric potential of the floating diffusion node FD. Namely, the CMOS image sensor converts incident light into electric signals by detecting the difference between the initial electric potential (i.e., the reference electric potential) of the floating diffusion node FD and the electric potential (i.e., the data electric potential), which is decreased due to the charge transferred to the floating diffusion node FD.

The lower the operation voltage of a CMOS image sensor is, the narrower the dynamic range of the floating diffusion node FD is, and the worse the signal transfer efficiency of the transfer transistor 120 is. Therefore, a CMOS image sensor having a wide dynamic range and an enhanced signal transfer efficiency of the transfer transistor 120 is desired.

Korean Patent Laid-Open Publication No. 2003-9625 discloses a method for improving the efficiency of the charge transfer from a photo diode to a floating diffusion node. In the Publication No. 2003-9625, a driving clock for driving the gate of the transfer transistor is coupled to an electric potential of a floating diffusion node. However, the method cannot be easily implemented because it is difficult to form the floating diffusion node (or floating diffusion region), since an electrode of the transfer gate is expanded to the floating diffusion region.

That is, it is difficult to use a gate electrode self-aligned ion implantation technique so as to form the floating diffusion region. Therefore, when a transfer gate electrode is formed after a floating diffusion region is formed, an additional photo mask process is required, so that a manufacturing process becomes more complicated and manufacturing costs increase. In addition, it is difficult to guarantee electrical characteristics of the transfer transistor because of the difficulty in designing and controlling a channel width of the transfer transistor.

### SUMMARY OF THE INVENTION

Exemplary embodiments of the present disclosure provide a unit pixel of a complementary metal-oxide semiconductor (CMOS) image sensor for widening a dynamic range of the CMOS image sensor and/or enhancing charge transfer efficiency. Other exemplary embodiments of the present disclosure also provide a pixel array of a CMOS image sensor for widening a dynamic range of the CMOS image sensor and enhancing charge transfer efficiency. Still other exemplary embodiments of the present disclosure also provide a CMOS image sensor for widening a dynamic range of image sensor and enhancing charge transfer efficiency.

In some exemplary embodiments of the present disclosure, a unit pixel of a CMOS image sensor includes a photoelectric conversion element configured to generate a charge based on incident light; a transfer transistor configured to transfer the charge integrated in the photoelectric conversion element to a floating diffusion node in response to a transfer control signal; a boosting capacitor disposed between a gate of the transfer transistor and the floating diffusion node; and a signal transfer circuit configured to transfer an electric potential of the floating diffusion node in response to a selection signal.

In further embodiments, the boosting capacitor may be a metal-insulator-metal (MIM) capacitor or a poly-insulator-poly (PIP) capacitor. The signal transfer circuit may include a source follower transistor of which a gate is connected to the floating diffusion node and of which a drain is connected to a power source. In addition, the signal transfer circuit may further include a selection transistor serially connected to the source follower transistor. The unit pixel of a CMOS image sensor may further include a reset transistor that resets an electric potential of the floating diffusion node so that the floating diffusion node may have an initial electric potential in response to a reset control signal.

In other exemplary embodiments of the present disclosure, a pixel array of a CMOS image sensor includes a plurality of photoelectric conversion elements, each of the photoelectric conversion elements being configured to generate a charge based on incident light, respectively; a plurality of transfer transistors, each of the transfer transistors being configured to transfer the charge integrated in the corresponding photoelectric conversion element to a floating diffusion node in response to one of a plurality of transfer control signals, respectively; a plurality of boosting capacitors disposed over boundaries of adjacent photoelectric conversion elements, each of the boosting capacitors being electrically coupled between a gate of the corresponding transfer transistor and the floating diffusion node, respectively; and a signal transfer circuit configured to transfer an electric potential of the floating diffusion node in response to a selection signal.

In further embodiments, the signal transfer circuit may include a source follower transistor of which a gate is coupled to the floating diffusion node and of which a drain is coupled to a power source. The signal transfer circuit may further include a selection transistor serially coupled to the source follower transistor.

In still other exemplary embodiments of the present disclosure, a pixel array of a CMOS image sensor includes a plurality of photoelectric conversion elements, each of the photoelectric conversion elements being configured to generate a charge based on incident light, respectively; a plurality of transfer transistors, each of the transfer transistors being configured to transfer the charge integrated in the corresponding photoelectric conversion element to one of a plurality of floating diffusion nodes in response to one of a plurality of transfer control signals, respectively; a plurality of boosting capacitors disposed over boundaries of adjacent photoelectric conversion elements, each of the boosting capacitors being electrically coupled between a gate of the corresponding transfer transistor and the corresponding floating diffusion node, respectively; and a plurality of signal transfer circuits, each of the signal transfer circuits being configured to transfer an electric potential of the corresponding floating diffusion node in response to one of a plurality of selection signals, respectively.

In still other exemplary embodiments of the present disclosure, a CMOS image sensor includes a plurality of photoelectric conversion elements, each of the photoelectric conversion elements being configured to generate a charge based on incident light, respectively; a plurality of transfer transistors, each of the transfer transistors being configured to transfer the charge integrated in the corresponding photoelectric conversion element to a floating diffusion node in response to one of a plurality of transfer control signals, respectively; a plurality of boosting capacitors disposed over boundaries of adjacent photoelectric conversion elements, each of the boosting capacitors being electrically coupled between a gate of the corresponding transfer transistor and the floating diffusion node, respectively; a signal transfer circuit configured to transfer an electric potential of the floating diffusion node in response to a plurality of selection signals; and an internal circuit configured to sample the electric potential transferred from the signal transfer circuit.

In still other exemplary embodiments of the present disclosure, a CMOS image sensor includes a plurality of photoelectric conversion elements, each of the photoelectric conversion elements being configured to generate a charge based on incident light, respectively; a plurality of transfer transistors, each of the transfer transistors being configured to transfer the charge integrated in the corresponding photoelectric conversion element to one of a plurality of floating diffusion nodes in response to one of a plurality of transfer control signals, respectively; a plurality of boosting capacitors disposed over boundaries of adjacent photoelectric conversion elements, each of the boosting capacitors being electrically coupled between a gate of the corresponding transfer transistor and the corresponding floating diffusion node, respectively; a plurality of signal transfer circuits, each of the signal transfer circuits being configured to transfer an electric potential of the corresponding floating diffusion node in response to one of a plurality of selection signals, respectively; and an internal circuit configured to sample the electric potentials transferred from the signal transfer circuits.

In further embodiments, the internal circuit may include a sampling circuit and an amplifying circuit. The internal circuit may include a correlated double sampler, and may sample the electric potentials transferred from the plurality of signal transfer circuits using the correlated double sampler.

Therefore, a dynamic range of the electric potential of the floating diffusion node may be widened. In addition, a drain-source voltage difference of the transfer transistor may be increased, so that the charge transfer efficiency may be enhanced.

### BRIEF DESCRIPTION OF THE DRAWINGS

Features and advantages of the present disclosure will become more apparent by describing in detail exemplary embodiments thereof with reference to the accompanying drawings, in which:

FIG. 1 is a circuit diagram illustrating a conventional unit pixel of a 4-transistor structure complementary metal-oxide semiconductor (CMOS) image sensor;

FIG. 2 is a circuit diagram illustrating a unit pixel of a CMOS image sensor according to an exemplary embodiment of the present disclosure;

FIG. 3 is a timing diagram illustrating an operation of a unit pixel of CMOS image sensor according to an exemplary embodiment of the present disclosure;

FIG. 4 is a schematic diagram illustrating a surface potential of a unit pixel of a CMOS image sensor according to an exemplary embodiment of the present disclosure;

FIG. 5A is a plane view illustrating a layout of a unit pixel of a CMOS image sensor according to an exemplary embodiment of the present disclosure;

FIG. 5B is a vertical cross-sectional view taken along the line I-I′ of FIG. 5A;

FIG. 6 is a circuit diagram illustrating a pixel array of a CMOS image sensor according to an exemplary embodiment of the present disclosure;

FIG. 7 is a circuit diagram illustrating a pixel array of a CMOS image sensor according to another exemplary embodiment of the present disclosure;

FIG. 8 is a block diagram illustrating a CMOS image sensor according to an exemplary embodiment of the present disclosure; and

FIG. 9 is a block diagram illustrating a CMOS image sensor according to another exemplary embodiment of the present disclosure.

### DETAILED DESCRIPTION OF PREFERRED EMBODIMENTS

Exemplary embodiments of the present disclosure are disclosed herein. The specific structural and functional details shown are merely representative for purposes of describing the exemplary embodiments. Thus, the present invention may be embodied in many alternate forms and should not be construed as limited to the exemplary embodiments set forth herein.

Accordingly, while the invention is susceptible to various modifications and alternative forms, specific embodiments thereof are shown by way of example in the drawings and are described in detail herein. It shall be understood, however, that there is no intent to limit the invention to the particular exemplary forms described, but on the contrary, the invention is to cover all modifications, equivalents, and alternatives falling within its spirit and scope. Like numbers may refer to like elements throughout the descriptions of the figures.

It shall also be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

In addition, it shall be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etcetera).

The terminology used herein is for the purpose of describing particular embodiments and is not intended to be limiting of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

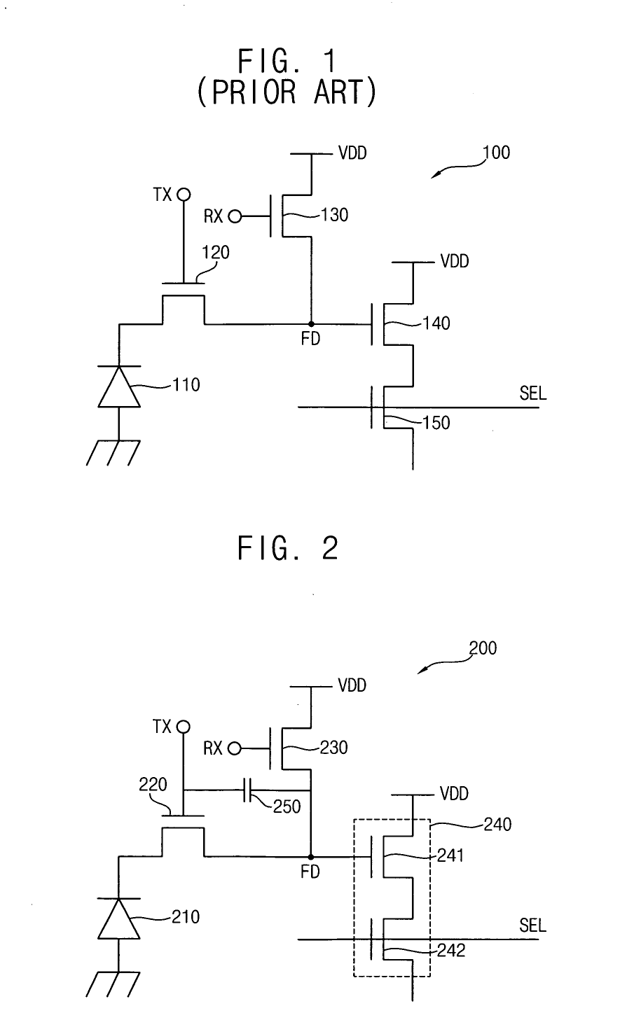

FIG. 2 is a circuit diagram illustrating a unit pixel of a complementary metal-oxide semiconductor (CMOS) image sensor that is indicated generally by the reference numeral 200, according to an exemplary embodiment of the present disclosure. Referring to FIG. 2, the unit pixel 200 of the CMOS image sensor includes a photoelectric conversion element 210, a transfer transistor 220, a reset transistor 230, a signal transfer circuit 240 and a boosting capacitor 250. The photoelectric conversion element 210 integrates photo-generated charge on the basis of incident light. For example, the photoelectric conversion element 210 may be a photodiode. The transfer transistor 220 transfers the photo-generated charge integrated in the photoelectric conversion element 210 to a floating diffusion node FD in response to a transfer control signal TX.

The reset transistor 230 resets the floating diffusion node FD so that the floating diffusion node FD may have an initial electric potential in response to a reset control signal RX. For example, the reset transistor 230 may reset the floating diffusion node FD so that the floating diffusion node FD may have approximately a level of a power supply voltage VDD.

The reset control signal RX is applied to a gate electrode of the reset transistor 230 and the power supply voltage VDD is applied to a drain electrode of the reset transistor 230. In addition, a source electrode of the reset transistor 230 is connected to the floating diffusion node FD.

The signal transfer circuit 240 transfers the electric potential of the floating diffusion node FD to the internal circuit in response to a selection signal SEL. For example, the signal transfer circuit 240 may transfer the electric potential of the floating diffusion node FD to an internal circuit in response to the selection signal SEL. The internal circuit may include a sampling circuit, an amplification circuit and so on. The internal circuit may sample the electric potential of the floating diffusion node FD using a correlated double sampling method.

The signal transfer circuit 240 may include a source follower transistor 241 and a selection transistor 242. The signal transfer circuit 240 may be modified in alternate embodiments. For example, the signal transfer circuit 240 might not include a source follower transistor but might include only a selection transistor, a drain of which is connected to the floating diffusion node FD.

The source follower transistor 241 outputs an electric potential of the floating diffusion node FD inputted to a gate electrode of the source follower transistor 241 through a source electrode of the source follower transistor 241. The gate electrode of the source follower transistor 241 is connected to the floating diffusion node FD and the drain electrode to the power supply voltage VDD.

The selection transistor 242 transfers the electric potential of the floating diffusion node FD detected by the source follower transistor 241 in response to a selection signal SEL. The selection transistor 242 is serially connected to the source follower transistor 241. More specifically, a drain electrode of the selection transistor 242 is connected to the source electrode of the source follower transistor 241 and the selection signal SEL is applied to a gate electrode of the selection transistor 242.

The boosting capacitor 250 is connected between a gate electrode of the transfer transistor 220 and the floating diffusion node FD. For one example, the boosting capacitor 250 may be a metal-insulator-metal (MIM) capacitor. For another example, the boosting capacitor 250 may be a poly-insulator-poly (PIP) capacitor. By inserting the boosting capacitor 250 having a desired capacitance between the gate electrode of the transfer transistor 220 and the floating diffusion node FD, a boosting effect may be achieved.

The capacitance of the boosting capacitor 250 may be determined depending upon a degree of a required boosting level. For example, a boosting capacitor having about 1 pF of a capacitance may be used so that the electric potential of the floating diffusion node FD may have about 0.7 volts of a boosting level.

Hereinafter, an operation of the unit pixel of the CMOS image sensor illustrated in FIG. 2 will be described. When a reset control signal RX having the level of the power supply voltage VDD is applied to the gate electrode of the reset transistor 230, the electric potential of the floating diffusion node FD rises to about the level of the power supply voltage VDD. After the electric potential of the floating diffusion node FD is reset to about the level of the power supply voltage VDD, the electric potential of the floating diffusion node FD is sampled by the signal transfer circuit 240 and becomes the initial electric potential of the floating diffusion node.

The boosting capacitor 250 boosts the electric potential of the floating diffusion node FD when the transfer control signal TX having the level of the power supply voltage VDD is applied. That is, when the reset control signal RX is at the level of the power supply voltage VDD and the transfer control signal TX is at the level of a ground electric potential, the electric potential of the floating diffusion node FD rises to about the level of the power supply voltage VDD, and charges corresponding to the level of the power supply voltage VDD are integrated in both ends of the boosting capacitor 250. After the reset control signal RX is deactivated to have the level of the ground electric potential, the transfer control signal TX rises to the level of the power supply voltage VDD so that the electric potential of the floating diffusion node FD is boosted according to the charges integrated in the boosting capacitor 250. For example, the electric potential of the boosting capacitor may be increased above the level of the power supply voltage VDD.

During a photo integration period, electron hole pairs (EHP) are generated in the photoelectric conversion element 210. The number of electron hole pairs generated in the photoelectric conversion element 210 is proportional to an intensity of the light incident onto the photoelectric conversion element 110.

After the reset control signal RX is deactivated to have the ground electric potential level, the transfer control signal TX is activated to have the level of the power supply voltage VDD and a channel is established in the transfer transistor 220 so that the charge integrated in the photoelectric conversion element 210 is transferred to the floating diffusion node FD. The electric potential of the floating diffusion node FD falls proportionally to the charge, which is transferred from the photoelectric conversion element 210 to the floating diffusion node FD, and an electric potential of the source electrode of the source follower transistor 241 varies as a result. When the transfer control signal TX is deactivated to have the level of the ground electric potential, the voltage boosting due to the charge accumulated in the boosting capacitor 250 is finished.

When the selection signal SEL is activated and the selection transistor 242 is turned on, the electric potential of the floating diffusion node FD is transferred to the internal circuit by the source follower transistor 241 and the selection transistor 242, and becomes a data electric potential. A light sensing operation of the CMOS image sensor may be performed by a correlation double sampling (CDS). For example, the light sensing operation is performed by comparing the data electric potential to the initial electric potential of the floating node. After the light sensing operation finishes, the reset operation of the floating diffusion node FD is repeated and the other operations stated above are repeated.

By inserting the boosting capacitor 250 between the gate electrode of the transfer transistor 220 and the floating diffusion node FD, the electric potential of the floating diffusion node FD may be boosted in response to the activation of the transfer control signal TX. Therefore, a dynamic range of the electric potential of the floating diffusion node may be widened and a drain-source voltage difference of the transfer transistor 220 may be increased, so that charge transfer efficiency may be enhanced.

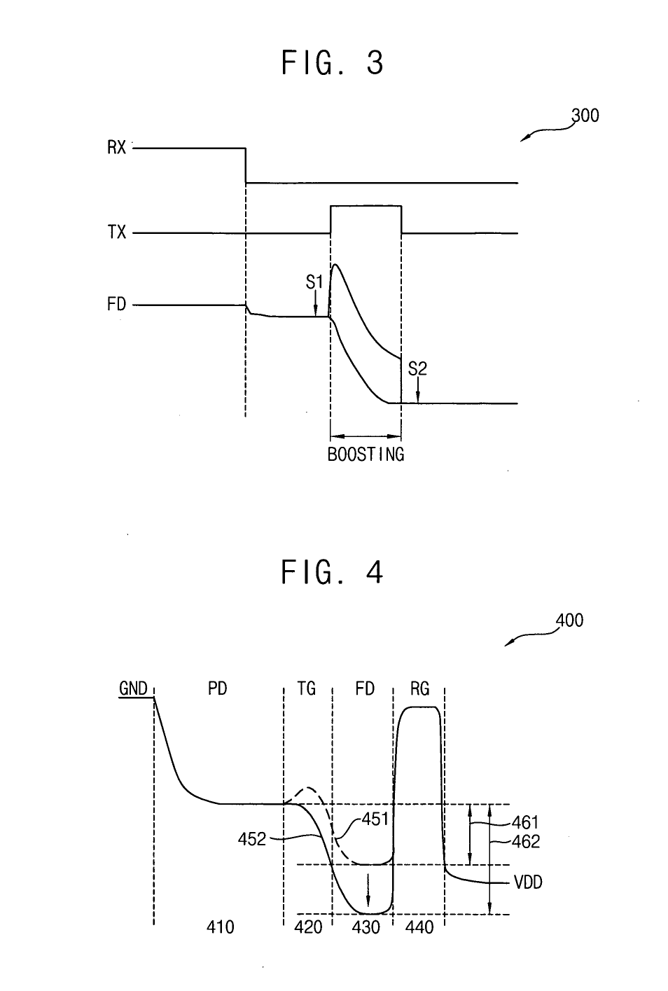

FIG. 3 is a timing diagram illustrating an operation of a unit pixel of a CMOS image sensor that is indicated generally by the reference numeral 300, according to an exemplary embodiment of the present disclosure. Referring to FIG. 3, when the reset control signal RX is activated to the level of the power supply voltage VDD, the electric potential of the floating diffusion node FD is reset so that the floating diffusion node FD may have about the level of the power supply voltage VDD. After the electric potential of the floating diffusion node FD is reset, the electric potential of the floating diffusion node FD is sampled by the signal transfer circuit at a stage of S1.

When the electric potential of the floating diffusion node is reset so that the floating diffusion node FD may have about the level of the power supply voltage VDD while the transfer control signal TX is deactivated, charges are integrated in both ends of the boosting capacitor 250. After the reset control signal RX is deactivated to have the ground electric potential level, the transfer control signal TX is activated to have the level of the power supply voltage VDD. According to the activation of the transfer control signal TX, a voltage of the floating diffusion node is boosted due to the charge integrated in the boosting capacitor 250 as shown in FIG. 3.

Because the transfer control signal TX is activated to have the level of the power supply voltage VDD, a channel is established in the transfer transistor and the electric potential of the floating diffusion node FD falls proportionally to the charge transferred from the photoelectric conversion element. When the transfer control signal TX that was activated to the level of the power supply voltage VDD is deactivated to have the ground electric potential level, the boosting operation finishes and the electric potential of the floating diffusion node FD falls. After the boosting operation finishes, the electric potential of the floating diffusion node FD is sampled as the data electric potential by the signal transfer circuit at a stage of S2.

FIG. 4 is a schematic diagram illustrating a surface potential of a unit pixel of a CMOS image sensor that is indicated generally by the reference numeral 400, according to an exemplary embodiment of the present disclosure. Referring to FIG. 4, an electric potential of a photoelectric conversion element region 410, an electric potential of a transfer transistor region 420, an electric potential of a floating diffusion node region 430 and an electric potential of a reset transistor region 440 are explained.

A potential well is formed in the photoelectric conversion element region 410. During a photo integration period, charges are integrated in the potential wall of photoelectric conversion element region 410. After the photo integration period, the transfer control signal TX is activated to have the level of the power supply voltage VDD, and the electric potential of the transfer transistor 420 rises. As the charge integrated in the potential well of photoelectric conversion element region 410 is transferred to the floating diffusion node FD, the electric potential of the floating diffusion node FD falls proportionally to the charge transferred.

As shown in FIG. 4, in comparison with a unit pixel 451 of the conventional CMOS image sensor, an efficiency of charge transfer of a unit pixel 452 of the CMOS image sensor according to an exemplary embodiment of the present disclosure is improved because the electric potentials of the transfer transistor region 420 and the floating diffusion node region 430 are increased compared with the unit pixel 451 of the conventional CMOS image sensor. The improvement of transfer efficiency results from the boosting operation caused by the charge integrated in the boosting capacitor as explained for FIGS. 2 and 3.

Because the electric potential of the transfer transistor region 420 and the floating diffusion node region 430 is increased compared with the unit pixel 451 of the conventional CMOS image sensor, the potential well of the photoelectric conversion element region 410 can be deeper compared with that of the unit pixel 451 of the conventional CMOS image sensor so that a charge integration capacity of the photoelectric conversion element can be increased. In addition, in comparison with a dynamic range 461 of a unit pixel of the conventional CMOS image sensor, a dynamic range of a unit pixel 462 of the CMOS image sensor according to an exemplary embodiment of the present disclosure is advantageously increased.

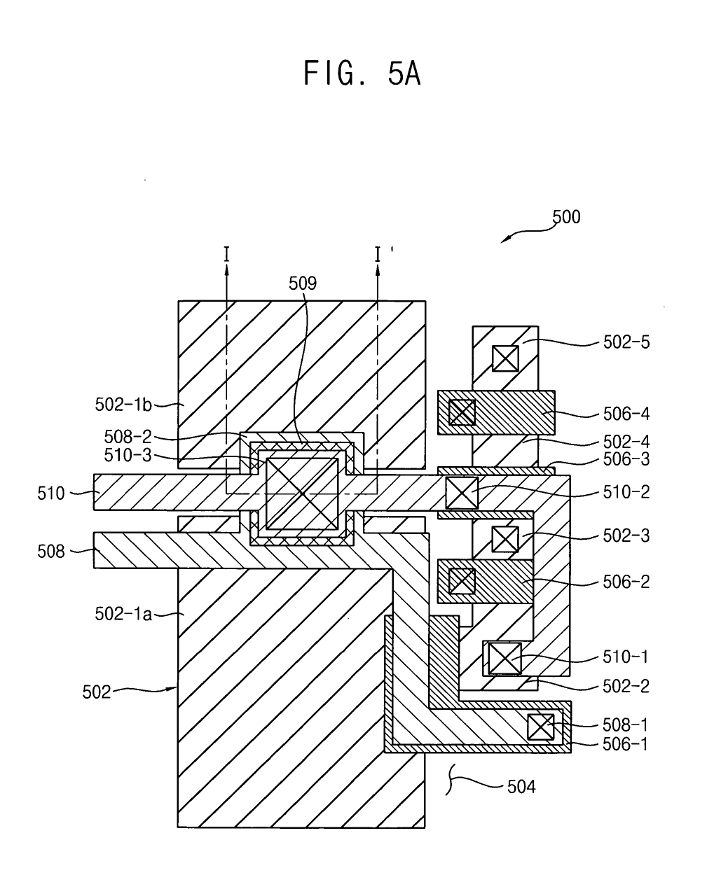

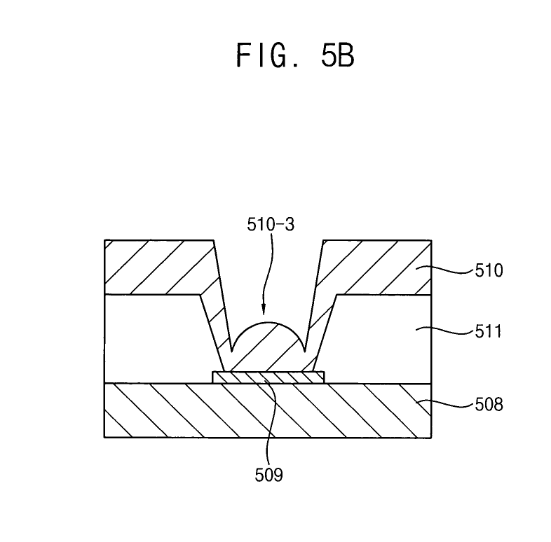

FIG. 5A is a plane view illustrating a layout of a unit pixel of a CMOS image sensor that is indicated generally by the reference numeral 500, according to an exemplary embodiment of the present disclosure, and FIG. 5B is a vertical cross-sectional view taken along the line I-I′ of FIG. 5A. Referring to FIGS. 5A and 5B, an active region 502 is surrounded by an isolation region 504. The isolation region 504, which includes isolation layers filled in a trench formed on a substrate, isolates the active regions 502 electrically and physically. The active region 502 includes photo regions 502-1a and 502-1b, a floating diffusion region 502-2, a power supply region 502-3, a connection region 5024 and an output region 502-5.

The photo region 502-1a and the photo region 502-1b are disposed adjacent to each other in a column direction. The floating diffusion region 502-2 is disposed in the first side of the photo region 502-1a. A diffusion gate electrode layer 506-1 is formed between the photo region 501-1a and the floating diffusion region 502-2. A reset gate electrode layer 506-2 is formed between the floating diffusion region 502-2 and the power supply region 502-3. An amplification gate electrode layer 506-3 is formed between the power supply region 502-3 and the connection region 502-4. A selection gate electrode layer 506-4 is formed between the connection region 502-4 and the output region 502-5.

The diffusion gate electrode layer 506-1, the reset gate electrode layer 506-2, the amplification gate electrode layer 506-3 and the selection gate electrode layer 506-4 are formed as a polysilicon pattern on the active region 502 by forming gate insulation layers between the active region 502 and the layers 506-1, 506-2, 506-3, and 506-4. Ions are implanted, by using the polysilicon pattern as a mask, into the active region 502. The regions into which the ions are implanted are provided as the photo regions 502-1a and 502-1b, the floating diffusion region 502-2, the power supply region 502-3, the connection region 502-4 and the output region 502-5.

A first conductive or metal line layer 508 and a second metal line layer 510 are formed between the photo region 502-1a and the photo region 502-1b. The first metal line layer 508 is electrically connected to the transfer gate electrode layer 506-1 through a contact 508-1. An extended portion 508-2 of the first metal layer 508, which is extended from an edge of the photo region 502-1a toward an edge of the photo region 502-1b, is provided as a lower electrode of the boosting capacitor 250. A dielectric layer 509 is formed on the lower electrode 508-2 and an insulating interlayer 511 is formed on the dielectric layer 509. A contact hole is formed in the insulating interlayer 511 and the second metal line layer 510 is formed. The second metal line layer 510 is electrically connected to the floating diffusion region 502-2 through a contact 510-1 and electrically connected to the amplification gate electrode layer 506-3 through a contact 510-2. Referring to FIG. 5B, a portion 510-3 of the second metal line layer is contacted with an upper portion of the dielectric layer 509 and is provided as an upper electrode of the boosting capacitor 250. The power supply voltage VDD is applied to the contact 512, and the contact 514 is provided as an output terminal. As explained above, according to an exemplary embodiment of the present disclosure, the boosting capacitor 250 is formed as the MIM by using the first metal line layer 508 and the second metal line layer 510 so that influences on electric characteristics of transistors may be minimized.

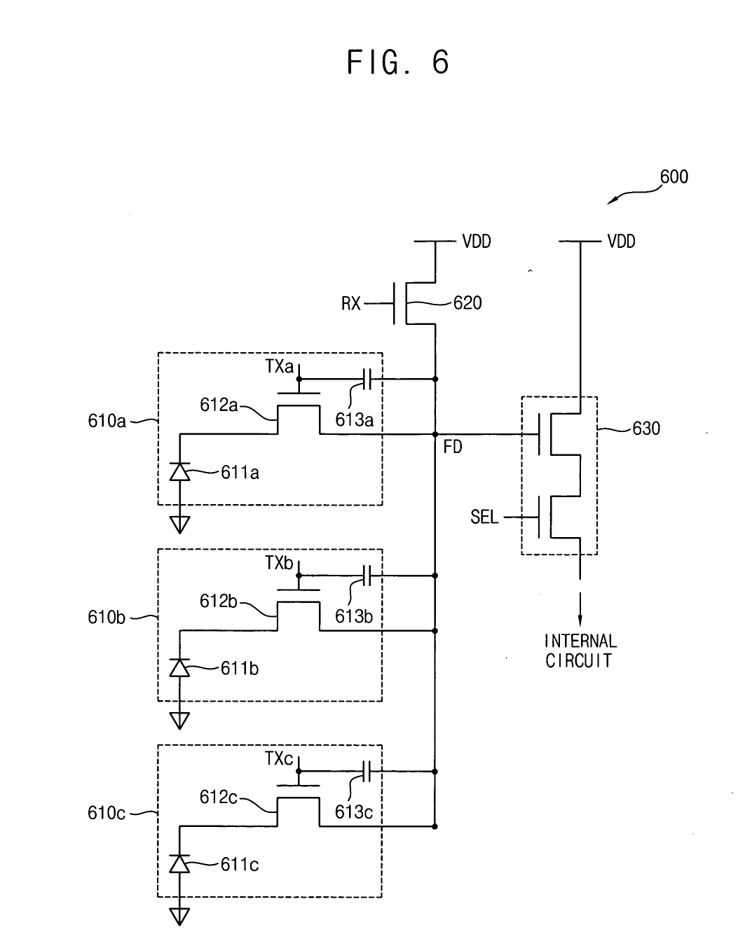

FIG. 6 is a circuit diagram illustrating a pixel array of a CMOS image sensor according to an exemplary embodiment of the present disclosure. Referring to FIG. 6, a pixel array, indicated generally by the reference numeral 600, includes unit pixels 610a, 610b and 610c, a reset transistor 620 and a signal transfer circuit 630.

Each of the unit pixels 610a, 610b and 610c has substantially the same structure as each other, i.e., each of the unit pixels 610a, 610b and 610c includes a photoelectric conversion element, a transfer transistor and a boosting capacitor. For example, the unit pixel 610a includes a photoelectric conversion element 611a, a transfer transistor 612a and a boosting capacitor 613a. Structures and operations of the photoelectric conversion element 611a, the transfer transistor 612a and the boosting capacitor 613a are substantially the same as the structure and operation explained in FIGS. 2 through 5.

The pixel array shown in FIG. 6 is a shared type pixel array in which the unit pixels 610a, 610b and 610c share the reset transistor 620 and the signal transfer circuit 630. The shared type pixel array may enhance an integration density of a CMOS image sensor by sharing the reset transistor 620 and the signal transfer circuit 630. The number of unit pixels sharing the reset transistor 620 and the signal transfer circuit 630 may be variable depending upon required specifications of a product.

The pixel array of the CMOS image sensor shown in FIG. 6 is a shared type pixel array in which unit pixels 610a, 610b and 610c share the reset transistor 620 and the signal transfer circuit 630 so that the unit pixels 610a, 610b and 610c share a floating diffusion node. Therefore, each of the transfer transistors 612a, 612b and 612c transfers the charge integrated in corresponding photoelectric conversion elements 611a, 611b and 611c to the floating diffusion node FD. In further detail, transfer transistors 612a, 612b and 612c transfer the charge integrated in the corresponding photoelectric conversion elements 611a, 611b and 611c to the floating diffusion node FD sequentially in response to corresponding transfer control signals TXa, TXb and TXc. When the transfer transistors 612a, 612b and 612c transfer the charge integrated in the corresponding photoelectric conversion elements 611a, 611b and 611c, a voltage boosting is generated by the boosting capacitors 613a, 613b and 613c. Before sensing each of the photoelectric conversion elements 611a, 611b and 611c, the floating diffusion node FD may be reset. Structure and operation of the reset transistor 620 and the signal transfer circuit 630 are substantially the same as the structure and operation of the reset transistor 230 and the signal transfer circuit 240 as shown in FIG. 2.

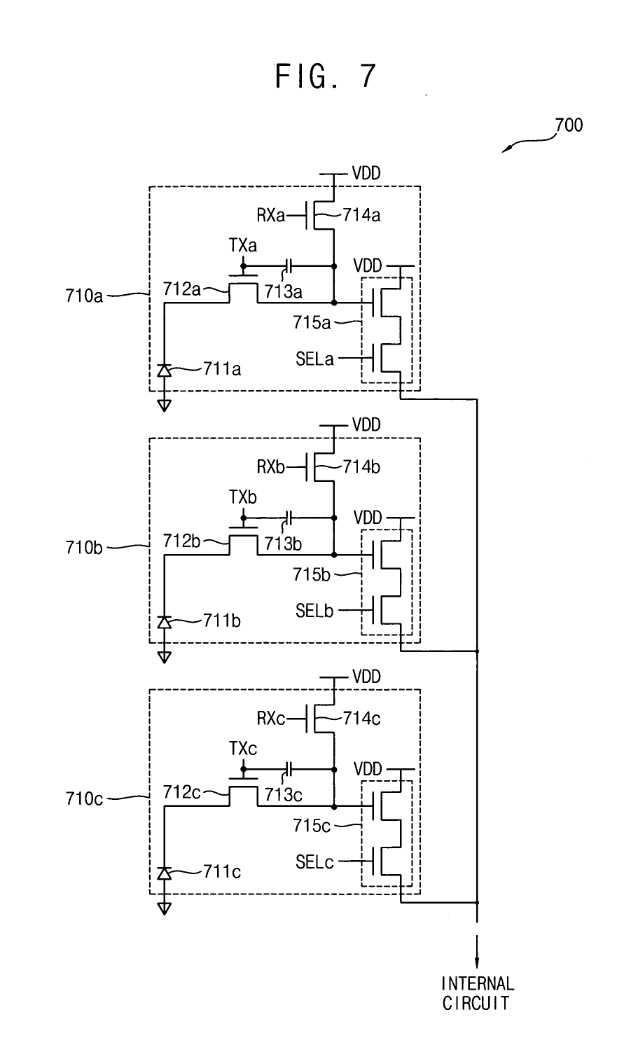

FIG. 7 is a circuit diagram illustrating a pixel array of a CMOS image sensor that is indicated generally by the reference numeral 700, according to another exemplary embodiment of the present disclosure. Referring to FIG. 7, the pixel array 700 of the CMOS image sensor includes unit pixels 710a, 710b and 710c.

Each of unit pixels 710a, 710b and 710c has substantially the same structure as each other, i.e., each of the unit pixels 710a, 710b and 710c includes a photoelectric conversion element, a transfer transistor, a boosting capacitor, a reset transistor and a signal transfer circuit. For example, the unit pixel 710a includes a photoelectric conversion element 711a, a transfer transistor 712a, a boosting capacitor 713a, a reset transistor 714a and a signal transfer circuit 715a. Structures and operations of the photoelectric conversion element 711a, the transfer transistor 712a, the boosting capacitor 713a, the reset transistor 714a and the signal transfer circuit 715a are substantially the same as the structure and operation explained in FIGS. 2 through 5.

In comparison with the pixel array shown in FIG. 6, the pixel array shown in FIG. 7 is a shared type pixel array in which each of the unit pixels has a reset transistor and a signal transfer circuit. Therefore, each unit pixel of the pixel array of FIG. 7 has a floating diffusion node.

The transfer transistors 712a, 712b and 712c transfer charge integrated in the corresponding photoelectric conversion elements 711a, 711b and 711c to the corresponding floating diffusion nodes FDa, FDb and FDc, sequentially, in response to corresponding transfer control signals TXa, TXb and TXc. When the transfer transistors 712a, 712b and 712c transfer charge integrated in the corresponding photoelectric conversion elements 711a, 711b and 711c, voltage boosting is generated in the boosting capacitors 713a, 713b and 713c. Before sensing each of the photoelectric conversion elements 711a, 711b and 711c, each of the corresponding floating diffusion nodes FDa, FDb and FDc may be reset.

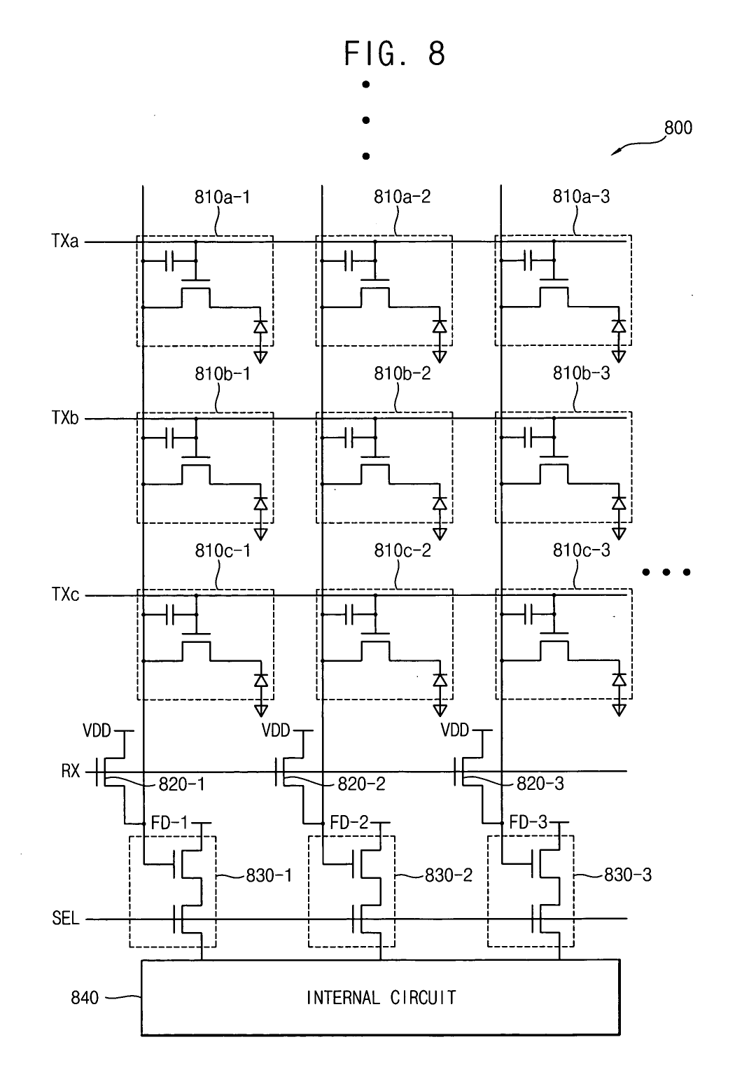

FIG. 8 is a block diagram illustrating a CMOS image sensor that is indicated generally by the reference numeral 800, according to an exemplary embodiment of the present disclosure. Referring to FIG. 8, the CMOS image sensor 800 includes a plurality of unit pixels 810a-1, 810b-1, 810c-1, . . . , 810a-2, 810b-2, 810c-2, . . . , 810a-3, 810b-3 and 810c-3, . . . reset transistors 820-1, 820-2 and 820-3, . . . , signal transfer circuits 830-1, 830-2 and 830-3, . . . , and an internal circuit 840. The unit pixels 810a-1, 810b-1, 810c-1, . . . , 810a-2, 810b-2, 810c-2, . . . , 810a-3, 810b-3 and 810c-3 each have a structure substantially the same as the structure of the unit pixel explained in FIG. 6.

The CMOS image sensor shown in FIG. 8 has a shared type pixel array. For example, unit pixels 810a-1, 810b-1 and 810c-1 share a reset transistor 820-1 and a signal transfer circuit 830-1; unit pixels 810a-2, 810b-2 and 810c-2 share a reset transistor 820-2 and a signal transfer circuit 830-2; and unit pixels 810a-3, 810b-3 and 810c-3 share a reset transistor 820-3 and a signal transfer circuit 830-3. Therefore, unit pixels 810a-1, 810b-1 and 810c-1 share a floating diffusion node FD-1 and unit pixels 810a-2, 810b-2 and 810c-2 share a floating diffusion node FD-2 and unit pixels 810a-3, 810b-3 and 810c-3 share a floating diffusion node FD-3.

Consequently, the transfer transistors included in each of the unit pixels, which share one floating diffusion node, transfer charge integrated in the corresponding photoelectric conversion element to the shared floating diffusion node sequentially. Namely, the transfer transistors transfer charge integrated in the corresponding photoelectric conversion elements to the corresponding floating diffusion node sequentially in response to corresponding transfer control signals TXa, TXb and TXc. When the transfer transistors transfer charge integrated in the corresponding photoelectric conversion elements, voltage boosting is generated by the boosting capacitors. Before sensing each of the photoelectric conversion elements, the floating diffusion node may be reset.

Signals transferred by the signal transfer circuits 830-1, 830-2 and 830-3 are sampled in the internal circuit 840. For example, the internal circuit 840 may include a sampling circuit, which samples signals read through the signal transfer circuit 830-1, 830-2 and 830-3, and an amplifying circuit, which amplifies a signal sampled in the sampling circuit. The internal circuit 840 may include a correlated double sampler, and may sample an electric potential of the floating diffusion nodes.

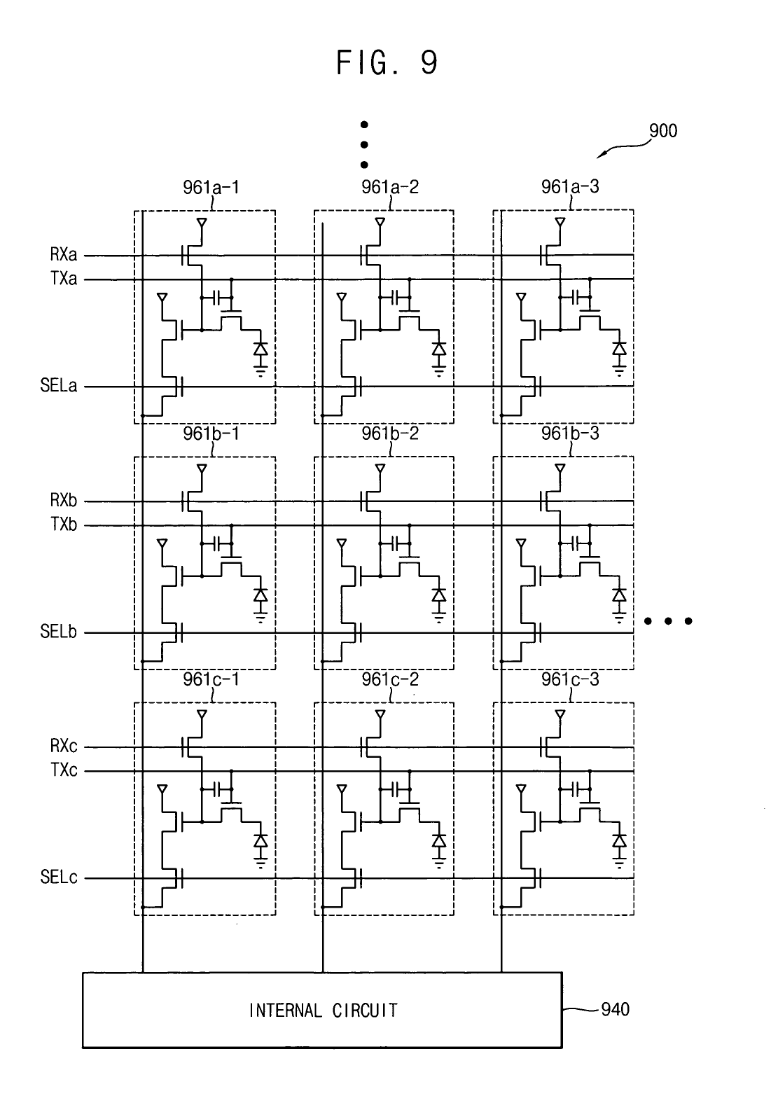

FIG. 9 is a block diagram illustrating a CMOS image sensor that is indicated generally by the reference numeral 900, according to another exemplary embodiment of the present disclosure. Referring to FIG. 9, the CMOS image sensor 900 includes a plurality of unit pixels 961a-1, 961b-1, 961c-1, 961a-2, 961b-2, 961c-2, 961a-3, 961b-3 and 961c-3, and an internal circuit 940.

The unit pixels 961a-1, 961b-1, 961c-1, 961a-2, 961b-2, 961c-2, 961a-3, 961b-3 and 961c-3 each have a structure substantially the same as the structure of the unit pixel explained in FIG. 7. Namely, each of the unit pixels 961a-1, 961b-1, 961c-1, 961a-2, 961b-2, 961c-2, 961a-3, 961b-3 and 961c-3 has a reset transistor and a signal transfer circuit. Therefore, each of the unit pixels 961a-1, 961b-1, 961c-1, 961a-2, 961b-2, 961c-2, 961a-3, 961b-3 and 961c-3 is provided with an independent floating diffusion node.

The transfer transistors included in the CMOS image sensor transfer charge integrated in the corresponding photoelectric conversion elements to the corresponding floating diffusion node in response to corresponding transfer control signals TXa, TXb and TXc. When the transfer transistors transfer charge integrated in the corresponding photoelectric conversion elements, voltage boosting is generated in the boosting capacitors. In addition, before sensing each of the photoelectric conversion elements, the corresponding floating diffusion nodes may be reset.

Signals transferred by the signal transfer circuits are sampled in the internal circuit 940. For example, the internal circuit 940 may include a sampling circuit, which samples signals read through the signal transfer circuits, and an amplifying circuit, which amplifies a signal sampled in the sampling circuits. The internal circuit 940 may include a correlated double sampler, and may sample an electric potential of the floating diffusion nodes.

For example, a PIP type capacitor may be formed as the boosting capacitor in substantially the same region where the above-described MIM capacitor is formed, or alternatively, a PIM type boosting capacitor having polysilicon, dielectric layer and metal may be formed in substantially the same region where the above-described MIM capacitor is formed. In the PIP type capacitor, a polysilicon pattern corresponding to a gate electrode layer may be formed as a lower electrode of a capacitor, an insulation layer is formed on the lower electrode of the capacitor, and another polysilicon pattern may be formed as an upper electrode of the capacitor on the insulation layer.

According to the above-described unit pixel of the CMOS image sensor, the pixel array of the CMOS image sensor, and the CMOS image sensor, a boosting capacitor is interposed between the transmission transistor and the floating diffusion node, and the voltage of the floating diffusion node may be boosted when the transfer control signal applied to the transfer transistor is activated.

Particularly, a boosting capacitor having a desired capacitance is interposed between the transmission transistor and the floating diffusion node, and thus, a desired boosting effect may be obtained. Therefore, a dynamic range of the electric potential of the floating diffusion node may be widened, and a drain-source voltage difference of the transfer transistor may be increased, so that the charge transfer efficiency may be enhanced.

The foregoing is illustrative of the present invention and is not to be construed as limiting thereof. Although several exemplary embodiments of this invention have been described, those of ordinary skill in the pertinent art will readily appreciate that many modifications are possible to the exemplary embodiments without materially departing from the novel teachings and advantages of this disclosure. Therefore, all such modifications are intended to be included within the scope of this invention.

Accordingly, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims and their equivalents.

What is claimed is:

1. A unit pixel of a complementary metal-oxide semiconductor (CMOS) image sensor, comprising:
a photoelectric conversion element configured to generate a charge based on incident light;
a transfer transistor configured to transfer the charge integrated in the photoelectric conversion element to a floating diffusion node in response to a transfer control signal;
a boosting capacitor disposed between a gate of the transfer transistor and the floating diffusion node; and
a signal transfer circuit configured to transfer an electric potential of the floating diffusion node in response to a selection signal.

2. The unit pixel of claim 1, wherein the boosting capacitor is a metal-insulator-metal (MI M) capacitor.

3. The unit pixel of claim 1, wherein the boosting capacitor is a poly-insulator-poly (PIP) capacitor.

4. The unit pixel of claim 1, wherein the signal transfer circuit comprises
a source follower transistor of which a gate is coupled to the floating diffusion node and of which a drain is coupled to a power source.

5. The unit pixel of claim 4, wherein the signal transfer circuit further comprises a selection transistor serially coupled to the source follower transistor.

6. The unit pixel of claim 4, further comprising:
a reset transistor configured to reset an electric potential of the floating diffusion node in response to a reset control signal so that the floating diffusion node has an initial electric potential.

7. A pixel array of a CMOS image sensor, comprising:
a plurality of photoelectric conversion elements, each of the photoelectric conversion elements being configured to generate a charge based on incident light, respectively;
a plurality of transfer transistors, each of the transfer transistors being configured to transfer the charge integrated in the corresponding photoelectric conversion element to a floating diffusion node in response to one of a plurality of transfer control signals, respectively;
a plurality of boosting capacitors disposed over boundaries of adjacent photoelectric conversion elements, each of the boosting capacitors being electrically coupled between a gate of the transfer transistor and the floating diffusion node, respectively; and
a signal transfer circuit configured to transfer an electric potential of the floating diffusion node in response to a selection signal.

8. The pixel array of claim 7, wherein each of the boosting capacitors is a MIM capacitor.

9. The pixel array of claim 7, wherein each of the boosting capacitors is a PIP capacitor.

10. The pixel array of claim 7, wherein the signal transfer circuit comprises a source follower transistor of which a gate is coupled to the floating diffusion node and of which a drain is coupled to a power source.

11. The pixel array of claim 10, wherein the signal transfer circuit further comprises a selection transistor serially coupled to the source follower transistor.

12. The pixel array of claim 10, further comprising:
a reset transistor configured to reset an electric potential of the floating diffusion node so that the floating diffusion node has an initial electric potential in response to a reset control signal.

13. A pixel array of a CMOS image sensor, comprising:
a plurality of photoelectric conversion elements, each of the photoelectric conversion elements being configured to generate a charge based on incident light, respectively;
a plurality of transfer transistors, each of the transfer transistors being configured to transfer the charge integrated in the corresponding photoelectric conversion element to one of a plurality of floating diffusion nodes in response to one of a plurality of transfer control signals, respectively;
a plurality of boosting capacitors disposed over boundaries of adjacent photoelectric conversion elements, each of the boosting capacitors being electrically coupled between a gate of the transfer transistor and the corresponding floating diffusion node, respectively; and
a plurality of signal transfer circuits, each of the signal transfer circuits being configured to transfer an electric potential of the corresponding floating diffusion node in response to one of a plurality of selection signals, respectively.

14. The pixel array of claim 13, wherein each of the boosting capacitors is a MIM capacitor.

15. The pixel array of claim 13, wherein each of the boosting capacitors is a PIP capacitor.

16. The pixel array of claim 13, wherein each of the signal transfer circuits comprises a source follower transistor of which a gate is coupled to one of the floating diffusion nodes and of which a drain is coupled to a power source.

17. The pixel array of claim 16, wherein each of the signal transfer circuits further comprises a selection transistor serially coupled to the source follower transistor.

18. The pixel array of claim 16, further comprising:
a plurality of reset transistors, each of the reset transistors being configured to reset an electric potential of the corresponding floating diffusion node so that the corresponding floating diffusion node has an initial electric potential in response to one of a plurality of reset control signals.

19. A CMOS image sensor, comprising:
a plurality of photoelectric conversion elements, each of the photoelectric conversion elements being configured to generate a charge based on incident light, respectively;
a plurality of transfer transistors, each of the transfer transistors being configured to transfer the charge integrated in the corresponding photoelectric conversion element to a floating diffusion node in response to one of a plurality of transfer control signals, respectively;
a plurality of boosting capacitors disposed over boundaries of adjacent photoelectric conversion elements, each of the boosting capacitors being electrically coupled between a gate of the transfer transistor and the floating diffusion node, respectively;
a signal transfer circuit configured to transfer an electric potential of the floating diffusion node in response to a plurality of selection signals; and
an internal circuit configured to sample the electric potential transferred from the signal transfer circuit.

20. The CMOS image sensor of claim 19, wherein each of the boosting capacitors is a MIM capacitor.

21. The CMOS image sensor of claim 19, wherein each of the boosting capacitors is a PIP capacitor.

22. The CMOS image sensor of claim 19, wherein the signal transfer circuit comprises a source follower transistor of which a gate is coupled to the floating diffusion node and of which a drain is coupled to a power source.

23. The CMOS image sensor of claim 22, wherein the signal transfer circuit further comprises a selection transistor serially coupled to the source follower transistor.

24. The CMOS image sensor of claim 22, further comprising:
a reset transistor configured to reset the electric potential of the floating diffusion node so that the floating diffusion node has an initial electric potential in response to a plurality of reset control signals.

25. The CMOS image sensor of claim 24, wherein the internal circuit comprises a correlated double sampler configured to sample the electric potential transferred from the signal transfer circuit.

26. A CMOS image sensor comprising:
a plurality of photoelectric conversion elements, each of the photoelectric conversion elements being configured to generate a charge based on incident light, respectively;
a plurality of transfer transistors, each of the transfer transistors being configured to transfer the charge integrated in the corresponding photoelectric conversion element to one of a plurality of floating diffusion nodes in response to one of a plurality of transfer control signals, respectively;
a plurality of boosting capacitors disposed over boundaries of adjacent photoelectric conversion elements, each of the boosting capacitors being electrically coupled between a gate of the transfer transistor and the corresponding floating diffusion node, respectively;
a plurality of signal transfer circuits, each of the signal transfer circuits being configured to transfer an electric potential of the corresponding floating diffusion node in response to one of a plurality of selection signals, respectively; and
an internal circuit configured to sample the electric potentials transferred from the signal transfer circuits.

27. The CMOS image sensor of claim 26, wherein each of the boosting capacitors is a MIM capacitor.

28. The CMOS image sensor of claim 26, wherein each of the boosting capacitors is a PIP capacitor.

29. The CMOS image sensor of claim 26, wherein each of the signal transfer circuits comprises a source follower transistor of which a gate is coupled to one of the floating diffusion nodes and of which a drain is coupled to a power source.

30. The CMOS image sensor of claim 29, wherein each of the signal transfer circuits further comprises a selection transistor serially coupled to the source follower transistor.

31. The CMOS image sensor of claim 29, further comprising:
a plurality of reset transistors, each of the reset transistors configured to reset the electric potential of the corresponding floating diffusion node so that the corresponding floating diffusion node has an initial electric potential in response to one of a plurality of reset control signals.

32. The CMOS image sensor of claim 31, wherein the internal circuit comprises a correlated double sampler configured to sample the electric potentials transferred from the signal transfer circuits.
